(19) United States
(12) Patent Application Publication
(10) Pub. No.: US 2008/0023839 A9
(43) Pub. Date: Jan. 31, 2008

(54) Molybdenum-based electrode with carbon nanotube growth

(75) Inventors: Hongjie Dai, Sunnyvale, CA (US); Nathan R. Franklin, Santa Barbara, CA (US); Qian Wang, Mountain View, CA (US)

Correspondence Address: Attn: Robert J. Crawford;Crawford Maunu PLLC, Suite 390, 1270 Northland Drive, St. Paul, MN, 55120, US

(73) Assignee: The Board of Trustees of the Leland Stanford Junior University, Palo Alto, CA (US)

(21) Appl. No.: 11/389,927

(22) Filed: Mar. 27, 2006

Related U.S. Application Data
(62) Division of application No. 10/508,362, filed on Apr. 4, 2005, now abandoned.
(60) Provisional application No. 60/377,007, filed on Apr. 30, 2002.
(60) Provisional application No. 60/366,451, filed on Mar. 20, 2002.

(51) Int. Cl. H01L 23/48

(52) U.S. Cl. 257/763

(57) ABSTRACT

A carbon nanotube is formed on at least one Molybdenum-based electrode. In one embodiment, a carbon-nanotube device includes a pair of Molybdenum-based electrodes over respective terraces. Using a catalyst on the Molybdenum-based material of at least one electrode, a carbon nanotube is grown over a gap that separates the terraces to connect the Molybdenum-based electrodes. Yet other aspects of the present invention employ carbon nanotubes extending (suspended) from respective Molybdenum-based structures for use in electrically addressable devices. The nanotubes can also be formed by patterned growth to bridge such Molybdenum-based electrodes. A particular method for manufacturing this device does not require post-growth processing. Applications include, among many others, scalable nanotube transistors/switches nano-electromechanical systems.

### RELATED PATENT DOCUMENTS

This application is a Divisional of U.S. patent application Ser. No. 10/508,362 filed on Apr. 4, 2005 and entitled “Molybdenum-Based Electrode with Carbon Nanotube Growth,” to which priority is claimed under 35 U.S.C. §121; U.S. patent application Ser. No. 10/508,362 was filed pursuant to 35 U.S.C. §371 and claims the benefit of International Application No. PCT/US2003/008569, filed on Mar. 20, 2003, which claims priority under 35 U.S.C. §120 to U.S. Provisional Patent Applications, Ser. No. 60/336,451 filed on 20 Mar. 2002, and Ser. No. 60/377,007 filed on Apr. 30, 2002; this application claims benefit/priority to each of the above-referenced patent documents.

### FEDERALLY SPONSORED RESEARCH OR DEVELOPMENT

This invention was made with Government support under contract N00014-01-0651 awarded by the Department of the Navy ONR. The U.S. Government has certain rights in this invention.

### FIELD OF THE INVENTION

The present invention relates generally to carbon nanotubes and more particularly to the growth of carbon nanotubes from Molybdenum-based electrodes.

### BACKGROUND

Carbon nanotubes are unique carbon-based, molecular structures that exhibit interesting and useful electrical properties. There are two general types of carbon nanotubes, referred to as multi-walled carbon nanotubes (MWNTs) and single-walled carbon nanotubes (SWNTs). SWNTs have a cylindrical sheet-like, one-atom-thick shell of hexagonally-arranged carbon atoms, and MWNTs are typically composed of multiple coaxial cylinders of ever-increasing diameter about a common axis. Thus, SWNTs can be considered to be the structure underlying MWNTs and also carbon nanotube ropes, which are uniquely-arranged arrays of SWNTs.

Due to their unique electrical properties, carbon nanotubes are being studied for development in a variety of applications. These applications include, among others, chemical and bio-type sensing, field-emission sources, selective-molecule grabbing, nano-electronic devices, and a variety of composite materials with enhanced mechanical and electromechanical properties. More specifically, for example, in connection with chemical and biological detection, carbon nanotubes are being studied for applications including medical devices, environmental monitoring, medical/clinical diagnosis and biotechnology for gene mapping and drug discovery. For general information regarding carbon nanotubes, and for specific information regarding SWNTs and its applications, reference may be made generally to the above-mentioned patent documents, and also to: “Carbon Nanotubes: Synthesis, Structure, Properties and Applications,” M. S. Dresselhaus, G. Dresselhaus and Ph. Avouris (Eds.), Springer-Verlag Berlin Heidelberg, New York, 2001; and “T. Single-shell Carbon Nanotubes of 1-nm Diameter,” Iijima, S. & Ichihashi, Nature 363, 603-605 (1993).

In these and other carbon nanotube implementations, making electrical contact to carbon nanotubes, such as SWNTs, has been challenging. Previously-used processes sometimes involve masking a SWNT with resist during a metallization process and/or depositing SWNTs randomly on pre-formed electrodes. In addition, typical materials that have been used for making metal contacts for carbon nanotubes, such as gold or titanium, are difficult to implement with SWNT growth environments. For instance, chemical vapor deposition (CVD) growth environments used for producing high quality SWNTs require temperatures that can exceed 700 degrees Celsius, and in some implementations, approach 900 degrees Celsius. Such CVD environments are also highly reducing due to the presence of hydrogen gas, which is introduced either directly with CVD gas flow or as a byproduct of a CVD reaction that results in SWNT growth.

The above-discussed SWNT growth environments present significant chemical compatibility problems to many metals that could possibly be used for electrodes in SWNT devices. The high temperatures cause low melting point metals to “ball up” or even vaporize, making the electrode ineffective. The reducing hydrogen environment causes hydride formation in a majority of metals. Metals such as tungsten inhibit the growth of carbon nanotubes, making the implementation of such metals in connection with SWNT growth ineffective.

These and other impediments to the growth of SWNTs coupled to electrical contacts have presented challenges to the fabrication and implementation of SWNTs for a variety of applications.

### SUMMARY OF THE INVENTION

Various aspects of the present invention are directed to overcoming the above issues and to providing a nanoelectronic application involving a carbon-nanotube element connecting to one or more Molybdenum-based electrodes. In connection with the present invention, it has been discovered that Molybdenum functions as an electrode that is compatible with carbon nanotube growth processes.

According to one particular example embodiment, a carbon-nanotube arrangement includes a substrate, first and second terraces over the substrate and an either side of a gap separating the first terrace from the second terrace, Molybdenum-based material covering both terraces, and a carbon nanotube structure connecting to the Molybdenum-based material over the first silicon-based terrace and connecting to the second terrace. In most instances, a catalyst material, used to grow the carbon nanotube, remains on the Molybdenum-based material. In this manner, the carbon nanotube forms an electrical connection between the first and second based terraces.

In another example embodiment of the present invention, an arrangement for forming a carbon-nanotube device permits for growth of a carbon nanotube so as to form an electrical connection between first and second terraces, at least one of which is Molybdenum-based. The arrangement includes: a substrate; first and second terraces over the substrate and an either side of a gap separating the first terrace from the second terrace; at least a first Molybdenum-based material covering at least a portion of the first silicon-based terrace. A catalyst material can be formed on the Molybdenum-based material and used to grow the carbon nanotube to form an electrical connection between the first and second terraces.

Yet other aspects of the present invention employ carbon nanotubes extending (suspended) from respective Molybdenum-based structures for use in electrically addressable devices. The nanotubes are formed by patterned growth to bridge Molybdenum-based electrodes. A particular method for manufacturing this device does not require post-growth processing.

Other aspects of the present invention are directed to methods for forming a carbon-nanotube device. In one embodiment, the method includes forming at least one electrode including Molybdenum on a substrate; and growing a carbon nanotube extending from the at least one electrode.

In another embodiment, the method includes: sputtering Molybdenum onto an insulative substrate; patterning a photoresist mask over the sputtered Molybdenum; using the patterned photoresist mask, etching the sputtered Molybdenum to form at least two Molybdenum electrodes; forming a catalyst material on at least one of the two Molybdenum electrodes; and using chemical vapor deposition to grow a single-walled carbon nanotube that extends from the catalyst material.

The above summary of the present invention is not intended to describe each illustrated embodiment or implementation of the present invention. The figures and the associated discussion that follows describe further embodiments and implementations.

### BRIEF DESCRIPTION OF THE DRAWINGS

The invention may be more completely understood in consideration of the detailed description of various embodiments of the invention that follows in connection with the accompanying drawings, in which:

FIG. 1 is a top-down view of a carbon nanotube arrangement in which a suspended carbon nanotube is shown bridging a pair of Molybdenum-covered terraces, according to an example embodiment of the present invention;

FIGS. 2a, 2b and 2c are cross-sectional views of another carbon nanotube arrangement being formed at respective stages of development, also consistent with the present invention; and

FIG. 3 is a cross-sectional view of another carbon nanotube arrangement formed with a Molybdenum-based cantilever, also consistent with the present invention

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

The present invention is believed to be applicable to a variety of different types of devices, and the invention has been found to be particularly suited for manufacturing single-walled carbon nanotubes electrically coupled to an electrode. Applications of these various nanotube structures include, among many others, scalable and/or addressable nanotube transistors/switches and nano-electromechanical systems (NEMs). While the present invention is not necessarily limited to such applications, various aspects of the invention may be appreciated through a discussion of various examples using this context.

According to one aspect of the present invention, a Molybdenum-based electrode is used for making electrical contact to carbon nanotubes, such as single-walled carbon nanotubes (SWNTs). In connection with the present invention, it has been discovered that Molybdenum functions as an electrode that is compatible with carbon nanotube growth processes. The Molybdenum-based electrode is applicable for both suspended and unsuspended arrangements.

According to the present invention, various implementations are realized. In a first implementation, a carbon-nanotube device includes a dual terraces over which Molybdenum-based materials (usually, but not necessarily, the same material) cover at least a portion of each terrace. The terraces, which are separated, can be silicon-based, such as Si0₂ or Si. A carbon nanotube structure (including or composed of a carbon nanotube) connects over the separation or gap to from one of the Molybdenum-based materials to the other of the Molybdenum-based materials.

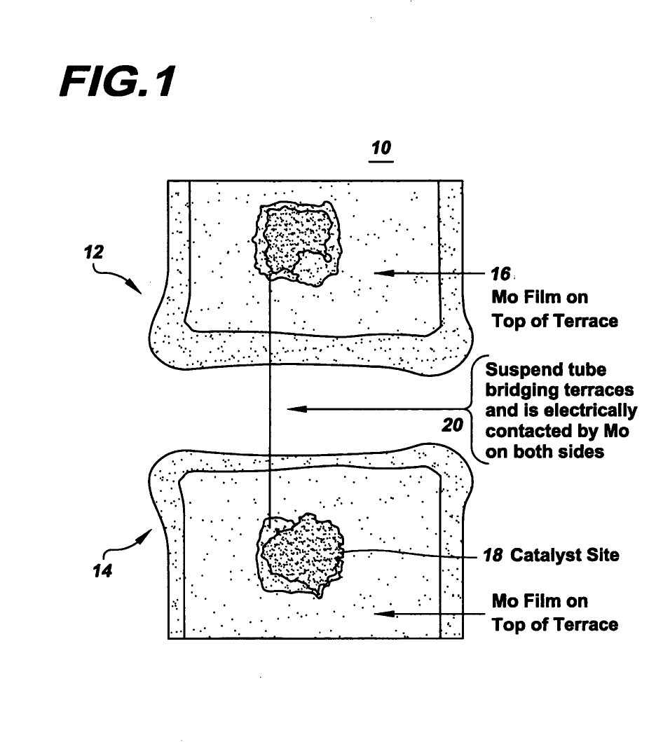

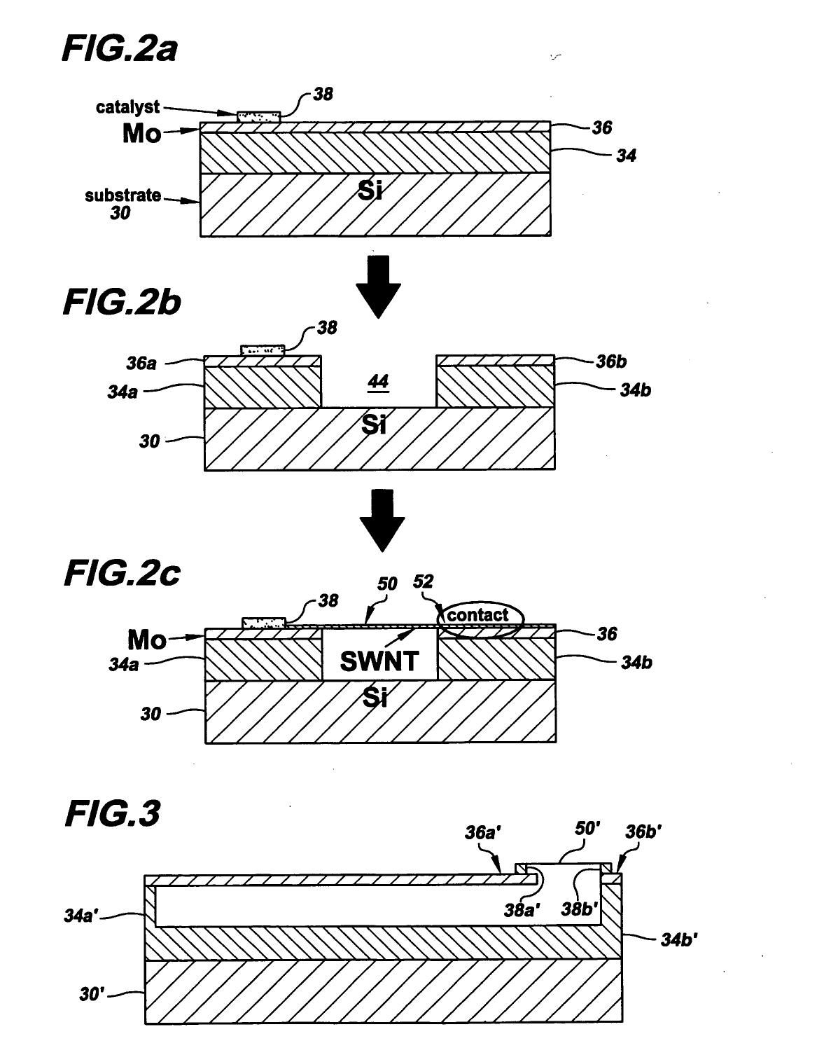

FIG. 1 illustrates such a carbon-nanotube device 10 from a top-down perspective. In this illustration, dual terraces 12 and 14 have been formed over a substrate (shown in FIG. 2a). Although other materials can be used to form the terraces, Silicon-based terraces are desirable in light of commercial equipment and processes available for tailoring the size and shapes of the terraces for a given application. Over the top surfaces of these terraces 12 and 14, one or more Molybdenum-based materials, such as a Molybdenum film 16, covers a sufficient portion of at least one of the terraces for depositing a carbon-nanotube-growth catalyst 18. A carbon nanotube 20 is then grown over a separation between the terraces 12 and 14 and extending from one of the Molybdenum-based locations to the other.

FIGS. 2a, 2b and 2c illustrate a similar carbon-nanotube device 30 being formed in stages from a cross-sectional, or side, perspective. In FIG. 2a, a substrate 30 is shown over which a terrace layer 34 is formed. A Molybdenum film 36 is then deposited over the terrace layer 34. A catalyst 38 is then deposited on the film 36 at one end of the illustrated structure. FIG. 2b illustrates the terrace layer 34 having been etched and divided into terrace 34a and terrace 34b to form a gap 44 over which the carbon nanotube is to be grown. In FIG. 2c, a carbon nanotube 50 is shown extending from terrace 34a to a contact area 52 over terrace 34b.

In another implementation, an arrangement is provided for forming such a carbon-nanotube device. The arrangement also includes such dual terraces over which Molybdenum-based materials are disposed. The arrangement is provided without the carbon nanotube structure connecting between the Molybdenum-based materials.

In one specific method implementation, SWNTs are grown extending from a pre-formed Molybdenum-based electrode in a CVD environment comprising hydrogen and having a temperature of at least about 700 degrees Celsius.

In another example embodiment of the present invention, Molybdenum (Mo) is sputtering onto a substrate sample for nanotube growth. In one implementation, the substrate is an insulating substrate. The sputtered Mo is then coated with photoresist and patterned to define electrodes on which SWNTs are to be coupled. The Mo is then etched away using a RIE (Reactive Ion Etch) environment comprising SF₆ and C₂ClF₅. The sample can then be used as is if nanotubes on the oxide surface are desired. In another implementation, the substrate is etched using 6:1 HF BOE (Buffered Oxide Etch) for silicon oxide substrates for suspension of SWNTs over the etched substrate. The substrate is etched to a distance similar to the desired length of the SWNT, which will ensure that nanotubes bridging the electrodes are suspended in the air. The photoresist is then removed with hot acetone.

The substrate is then coated with PMMA (poly-methyl methacrylate) to pattern the carbon nanotube catalyst at desired locations on the Mo electrodes. Wells for catalyst deposition are patterned with either DUV (Deep UV exposure) or E-beam lithography (or any other patterning techniques) and are subsequently developed. Alumina supported iron nitrate catalyst (and/or other types of catalyst) is then deposited into the wells for nanotube growth. The remaining catalyst and PMMA are lifted off in dichloroethane.

In an alternative implementation, the Mo film is first formed, followed by catalyst patterning and then etching of a trench in the substrate, with suspended SWNTs being grown across the etched trench. The tube is contacted by the Mo film on the opposing sides.

For both patterning approaches discussed above, SWNTs are grown using a mixture comprising methane and hydrogen, and in one implementation, with a small amount of ethylene. During the heat-up and cool-down processes with the SWNT growth, hydrogen is flowed across the substrate to eliminate the presence of oxygen, which could potentially oxidize the Molybdenum electrodes. The resulting structures include SWNTs bridging the electrodes, and the SWNTs can be electrically coupled to via the electrodes without necessarily further processing the SWNTs.

The present invention is capable of low resistance ohmic contacts to SWNTs as found by electrical measurements. Suspended and/or non-suspended SWNTs can be electrically contacted using the approaches described herein. With suspended SWNTs, further processing steps are not necessary for making contact to the SWNTs after their growth. This approach is particularly useful because typical processes for making such contact can often damage the suspended nanotubes (e.g., due to sagging down to the substrate via capillary forces involved in liquid processes).

Various aspects and implementations of the present invention readily yield suspended nanotube electrical devices and NEMs devices. For example, using the device 10 shown in FIG. 1 in which a suspended nanotube 20 is shown grown from catalyst sites 18 and bridging the Mo films 16, resistance between the terraces 12 and 14 is as low as 20 Kohms.

The present invention is extendible to obtaining suspended nanotubes with micro-mechanical structures of other materials such as Silicon (Si). FIG. 3 illustrates a nanotube 50′ bridging a suspended micromechanical Si ‘diving board’ (e.g., a cantilever) and a Si terrace. This micromechanical diving board includes an Mo film on a polySilicon base. The nanotube 50′ contacts Mo films 36a′ and 36b′ on the top surface of the diving board and the opposing Si terrace. This structure integrates Si microstructure with nanotube suspension, with the nanotube being electrically addressable.

The suspended SWNT device of FIG. 3 can be addressed electrically, and also mechanically and electro-mechanically using the micromechanical diving board. Since the Mo-based coating exists on both the cantilever and the terrace (FIG. 2a-c), the bridging nanotube is easily wired up through the opposing Mo electrodes. When bending the cantilever, an increase in the nanotube resistance can be observed due to mechanical stretching of the suspended SWNT.

According to another specific example method, the arrangements discussed above can be formed by using a substrate in the form of a p-type silicon wafer with 2-μm thermally grown oxide. A 50 nm thick Mo film is first deposited on the wafer by sputtering. Subsequently, photolithography and dry etching (e.g., reactive ion etching in SF₆ and C₂ClF₅ for removing Mo not protected by photoresist) are used to form two opposing Mo electrodes on SiO₂, followed by the use of 6:1 buffered HF to etch down the SiO₂ around the Mo electrodes by 1.5 μm. The photoresist on top of the Mo pattern is then removed for the catalyst-patterning step. The substrate is then coated with 1.6-μm thick layer of poly-methylmethacrylate (PMMA), patterned with deep ultra-violet light or electron beam, and developed to form wells in the PMMA film. An alumina-supported Fe catalyst suspended in methanol is then spun onto the substrate followed by lifted off in acetone. This leads to two catalyst islands formed on the two opposing Mo electrodes on top of the SiO₂ terraces. Other fabrication schemes for such substrate preparation have also been successful. For instance, one can first pattern catalyst on the Mo film, followed by defining the Mo electrodes and the subsequent formation of MO/SiO₂ terraces by wet etching.

Growth of SWNTs from the patterned catalyst islands can then be carried out in a 1″ CVD system. The growth can take place under a 72 mL/min flow of methane (99.999%) and a 10 mL/min co-flow of hydrogen at 900° C. for 5 min. During heating and cooling of the CVD reactor, with a constant flow of pure H₂ used in order to eliminate the possibility of oxygen impurities in the gas oxidizing the Mo electrodes.

Using Molybdenum (Mo) as an electrode material is an important aspect of this process. Unlike other metals, Mo has been discovered to be compatible with this CVD growth process of SWNTs at high temperatures. Other metals, including gold, titanium and tungsten, have failed for various reasons. After CVD growth, Au electrodes become discontinuous as gold balls up due to its relatively low melting temperature. Ti electrodes also fail as they become partially etched and thus highly resistive after growth. The etching phenomenon is explained by the formation of volatile metal hydrides at high temperatures in an environment containing hydrogen. This chemical incompatibility eliminates hydride-forming metals as electrode materials for nanotube growth at elevated temperatures. Mo and W are among the metals that do not form hydrides and are stable against aggregation at high temperatures. However, although W electrodes do survive the CVD growth process with high connectivity and conductivity, no SWNTs are found to grow from catalyst patterns on the W electrodes. The presence of W near the catalyst material appears to inhibit the growth of nanotubes, presumably caused by the high catalytic activity of W towards hydrocarbons, which interferes with SWNT formation in the CVD process. With Mo-based electrodes, SWNTs are frequently found to grow from electrodes to opposing ones, resulting in devices that comprise of suspended nanotubes bridging pairs of Mo electrodes. Also, it has been discovered that the Mo-based electrodes exhibit excellent conductivity after growth and allow for Ohmic contacts with nanotubes. This leads to suspended SWNT devices that can be measured electrically without any processing after nanotube synthesis.

In various implementations, the lengths of the suspended portion of the SWNTs are 3-10 μm, but can be either much shorter or longer. The portions of the nanotube overlapping with the Mo-based electrode surfaces provide electrical contact to the nanotube.

In one particular embodiment, these Mo-based devices are used to effect a field-effect transistor (FET) current operation with gate-voltage (Vg) characteristics that correspond to a p-type semiconducting SWNT due to oxygen doping (see P. G. Collins et al., Science 287, 1801 (2000), and R. Chen et al., Appl. Phys. Lett. 79, 6951 (2001)). A gate voltage is applied to the Si substrate, 2 μm away from the nanotube separated by an air gap and 0.5 μm thick oxide. The Si back-gate is still sufficient to increase or deplete carriers in suspended tubes. The ON state resistance of these suspended semiconducting SWNTs is typically about 100 k-1M, comparable to those grown on flat SiO₂ substrates and electrically contacted post growth.

The present invention has applications in suspended nanotube electronic devices and NEMs applications. The suspended nanotube can be implemented with mechanical oscillators for high speed communication, force transducers, mechanical sensors, biosensors and various other applications. In addition, the nanotubes described herein can be extended to form suspended, electrically-addressable nanowires, and as such are not limited to nanotubes. This type of nanotube exhibits excellent semiconducting FET characteristics, with a change of conductance by 6 orders of magnitude over a gate-voltage span of about 1.5 volt (gate oxide thickness 100 nm in this case). The transconductance of the FET is 90 nA/V, and the carrier mobility in the nanotube is calculated to be ˜10,000 cm2/Vs, 20 times higher than the hole mobility in single crystal S₁₁₇ at room temperature. This result illustrates that rational substrate design and simple chemical synthesis leads to advanced electronic devices.

The present invention is applicable to a variety of nanotube implementations, in addition to those discussed above. For more information, including information regarding methods for growing (suspended or not) carbon nanotubes for nanoelectronics and nano-electromechanical systems (NEMs) and applications, reference may be made to an article entitled, “Directed Growth of Free-Standing Single-Walled Carbon Nanotubes,” J. Am. Chem. Soc. 1999, 121, pp. 7975-7976, and to the previously-mentioned text entitled, “Carbon Nanotubes: Synthesis, Structure, Properties and Applications.”

While the present invention has been described with reference to several particular example embodiments, those skilled in the art will recognize that many changes may be made thereto without departing from the spirit and scope of the present invention.

What is claimed is:

1. An arrangement for forming a carbon-nanotube device, the arrangement comprising:
a substrate;
first and second silicon-based terraces over the substrate and an either side of a gap separating the first silicon-based terrace from the second silicon-based terrace;
a first Molybdenum-based material covering at least a portion of the first silicon-based terrace;
a second Molybdenum-based material covering at least a portion of the second silicon-based terrace, the first and second Molybdenum-based materials forming respective surfaces for supporting a carbon nanotube structure that forms an electrical connection between the Molybdenum-based materials.

2. The arrangement of claim 1, further including the carbon-nanotube structure electrically connecting between the Molybdenum-based materials.

3. The arrangement of claim 2, further including a catalyst material over the Molybdenum-based material and under the carbon-nanotube structure at each terrace.

4. A method for manufacturing a carbon-nanotube device, the method comprising:
forming at least one electrode including Molybdenum on a substrate; and
growing a carbon nanotube extending from the at least one electrode.

5. The method of claim 4, wherein growing a carbon nanotube includes growing a single-walled carbon nanotube using chemical-vapor deposition (CVD).

6. The method of claim 5, wherein growing a carbon nanotube includes growing a single-walled carbon nanotube in an environment having a temperature of at least about 700 degrees Celsius.

7. The method of claim 5, wherein growing a carbon nanotube includes growing a single-walled carbon nanotube in an environment comprising hydrogen gas.

8. A method for manufacturing a carbon-nanotube device, the method comprising:
sputtering Molybdenum onto an insulative substrate;
patterning a photoresist mask over the sputtered Molybdenum;
using the patterned photoresist mask, etching the sputtered Molybdenum to form at least two Molybdenum electrodes;
forming a catalyst material on at least one of the Molybdenum electrodes; and
using chemical vapor deposition (CVD), growing a single-walled carbon nanotube extending from the catalyst material and connecting the Molybdenum electrodes.

9. The method of claim 8, wherein growing a single-walled carbon nanotube includes growing the single-walled carbon nanotube in an environment comprising hydrogen and having a temperature of at least about 700 degrees Celsius.

10. A system for manufacturing a carbon-nanotube device, the system comprising:
means for forming at least one electrode including Molybdenum on a substrate; and
means for growing a carbon nanotube extending from the at least one electrode.
